(19) United States
(12) Patent Application Publication
(10) Pub. No.: US 2026/0005000 A1
(43) Pub. Date: Jan. 1, 2026

(54) ENHANCED SAFETY SYSTEM IN SUBSTRATE PROCESSING USING COMPRESSED DRY AIR

(71) Applicant: ASM IP Holding B.V., Almere (NL)

(72) Inventors: Arun Thottappayil, Phoenix, AZ (US); SangBaek Lee, Yongin-si (KR)

(21) Appl. No.: 19/248,699

(22) Filed: Jun. 25, 2025

Related U.S. Application Data
(60) Provisional application No. 63/665,464, filed on Jun. 28, 2024.

(51) Int. Cl. H01J 37/32; B08B 9/032; H01L 21/67

(52) U.S. Cl. CPC H01J 37/32522; B08B 9/0328; H01L 21/67017; H01J 37/32357; H01J 2237/002

(57) ABSTRACT

A safety system in substrate processing comprises a substrate processing apparatus configured to process the substrates, the apparatus comprising a chamber and a showerhead, an input line configured to receive a process cooling water (PCW) from an outside PCW source for cooling the substrate processing apparatus, an inlet valve disposed at an entrance of the input line to control the input of the PCW, a drain line configured to gather the PCW from the substrate processing apparatus used for cooling and exhaust the gathered PCW, a plurality of channels configured to connect between the input line and the drain line, and the PCW flows inside of the channels and a safety unit configured to inject a compressed dry air (CDA) into the input line and/or purge the CDA and the PCW from the plurality of channels and the drain line.

### CROSS-REFERENCE TO RELATED APPLICATIONS

This application claims priority to U.S. Provisional Patent Application Ser. No. 63/665,464 filed Jun. 28, 2024 titled ENHANCED SAFETY SYSTEM IN SUBSTRATE PROCESSING USING COMPRESSED DRY AIR, the disclosure of which is hereby incorporated by reference in its entirety.

### FIELD OF INVENTION

The present disclosure relates generally to a substrate processing system, more particularly to a substrate processing system using process cooling water (PCW) for heat management with a safety unit using a compressed dry air (CDA).

### BACKGROUND OF THE DISCLOSURE

A process cooling water (PCW) is used in some PEALD deposition chambers currently used for thermal regulation/management of various components. The components, for example, are chamber body, susceptor heaters, RPU's, and showerheads. The temperature range of operation is between 150° C. and 650° C.

The PCW serves a pivotal role of effectively cooling these high-temperature components and exhausting excessive heat during operation. The PCW cooling operation starts with the PCW injection from a PCW source (or PCW box) into the system by opening an inlet valve, which is electronically controlled. When a chamber alarm event occurs, this inlet valve is triggered to close to shut off the PCW flow into chamber components, thus preventing any potential hazards.

However, a significant danger arises when the inlet valve is triggered to close due to an alarm. In such an event, a significant volume of PCW (water) can be trapped inside the high-temperature chamber components (inside the channels assigned to the components). Each of the components, characterized by substantial thermal mass, exhibits extended cooling duration as it transitions from elevated operating temperature to ambient room temperature.

This thermal gradient creates a concern: the residual PCW trapped inside these components may undergo boiling (or evaporation). If the PCW inside the trapped channel boils, the pressure inside the channels can increase and it is a potential safety risk. Conventionally, when the channel pressure increases due to PCW evaporation and/or boiling, a person (usually an operator) should loosen a PCW channel fitting to release the pressure and tighten the fitting again before starting the PCW flow back to the chamber components.

Above procedures are prone to make mistakes so the present disclosure provides a system and a method with automatic safety features for substrate processing system using CDA.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with one embodiment there may be provided, an enhanced safety system using a process cooling water (PCW) in substrate processing, the system comprises: a substrate processing apparatus configured to process the substrates, the apparatus comprising a chamber and a showerhead; an input line configured to receive the PCW from an outside PCW source for cooling the chamber and the showerhead in the substrate processing apparatus; an inlet valve disposed at an entrance of the input line to control the input of the PCW into the input line; a drain line configured to gather the PCW from the substrate processing apparatus used for cooling the chamber and the showerhead and exhaust the gathered PCW; a plurality of channels configured to connect between the input line and the drain line, and the PCW flows inside of the channels, each of the plurality of channels is proximate to the chamber and the showerhead respectively; and a safety unit configured to inject a compressed dry air (CDA) into the input line and/or purge the CDA and the PCW from the plurality of channels and the drain line.

In an extended embodiment there may be provided, the safety unit further comprises an air tank configured to contain the CDA; an air inlet valve configured to control an injection of the CDA into the input line; an air outlet valve configured to control an exhaust of the CDA from the drain line; and a controller configured to control the open/close of the air inlet valve and the air outlet valve.

In an aspect, the controller further configured to monitor a status of the system.

In an aspect, the controller further configured to open the air inlet valve and the air outlet valve when a system alarm is triggered.

In an aspect, the time difference between openings of the air inlet valve and air outlet valve is equal to or less than 10 ms.

In accordance with another embodiment there may be provided, a safety securing method used in a substrate processing system, wherein the system comprises an input line for injecting process cooling water (PCW) for cooling the system and a drain line for exhausting the PCW from the system, the method comprises: monitoring a status of the system; determining whether the system status is on alarm; opening an air inlet valve to inject a compressed dry air (CDA) into the input line if the monitored status is on alarm; and opening an air outlet valve to purge the CDA and the PCW from the system if the monitored status is on alarm.

In an extended embodiment there may be provided, sending messages to an operator of the alarm and/or valve openings if the monitored status is on alarm.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 illustrates an overview of a substrate processing system with extended safety according to an embodiment of the present disclosure.

FIG. 2 illustrates a flowchart of the method for an extended safety used in a substrate processing system according to another embodiment of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

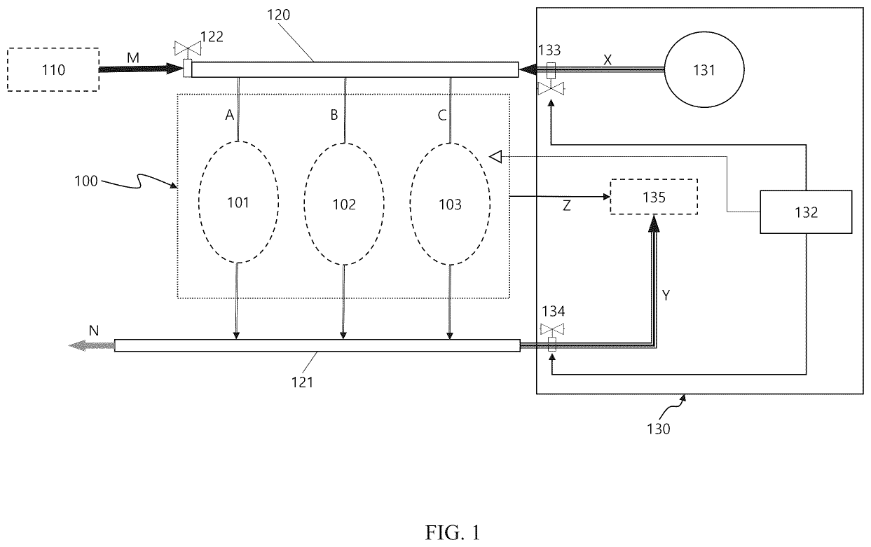

FIG. 1 illustrates an overview of a substrate processing system with extended safety according to an embodiment of the present disclosure.

An enhanced safety system in substrate processing according to an embodiment of the present disclosure may comprise a substrate processing apparatus 100, which may comprise a reaction chamber 101, a showerhead 102 and a remote plasma unit (RPU) 103. The components 101, 102, 103 may be examples and other components may also be comprised.

An input line 120 and a drain line 121 may be provided for thermal control of the components 101, 102, 103 in the apparatus 100. Each component may be provided with its own channel A, B, C for cooling down the temperature. Each channel A, B, C may be connected between the input line 120 and the drain line 121 so that PCW may flow through each of the channel A, B, C separately.

The PCW may come from a PCW source 110 outside of the system and the PCW may flow through an input flow path M into the input line 120. The PCW may flow into each of the channels A, B, C to cool down the components 101, 102, 103 and finally may flow into the drain line 121 and to the output flow path N for circulation.

In normal operation, the PCW may circulate starting from the PCW source 110 and finally return to the PCW source 110, where it may be recirculated. Some leaks may happen, and the leaks may be gathered into a leak tray 135 via leak path Z. An inlet valve 122 may control the PCW entry into the input line 120. The input line 120 may be electronically controlled so that it may be closed automatically anytime an abnormality happens to the system.

A safety unit 130 may comprise a controller 132, an air tank 131, an air inlet valve 133, and an air outlet valve 134. The safety unit 130 may also comprise an air inlet path X and an air outlet path Y. The air inlet path X may connect the air tank 131 and the input line 120 so that a compressed dry air (CDA) from the air tank 131 may flow into the input line 120. The air outlet path Y may connect the drain line 121 and the leak tray 135 so that the CDA and residual PCW may be purged out from the input line 120, from the channels A, B, C, and from the drain line 121 into the leak tray 135.

The controller 132 may be configured to monitor an operation status of the apparatus 100. The controller 132 may also be configured to control the open/close of the air inlet valve 133 and the air outlet valve 134.

When the operation status of the apparatus 100 is normal, the two valves 133, 134 may be closed. When the operation status of the apparatus 100 is abnormal (alarm triggering), the inlet valve 122 may be automatically closed and PCW circulation may be stopped. This means that hot PCW (water) may still remain in the input line 120, the drain line 121, and in each of the channels A, B, C.

Before the pressure of cooling paths in the system rises too much from the PCW boiling or evaporation, the controller 132 may detect this situation. Then the controller 132 may control the air inlet valve 133 to open so that the CDA from the air tank 131 may be injected into the inlet line 120. The controller 132 may control the air outlet valve 134 to close so that the residual PCW in the input line 120, in the drain line 121 and in the channels A, B, C may be purged out with the CDA from the air input valve 133 and the residual PCW. The opening sequence of the air input valve 133 and the opening sequence of the air output valve 134 may be done simultaneously. In the alternative, the sequence of opening the air input valve 133 and the air output valve 134 may be done interchangeably as long as a time difference between the two openings is less than a certain amount of time. For safety reasons, the certain amount of time difference between the two openings may be equal to or less than 10 ms.

With the purge, the pressure in the apparatus may go down below a safety threshold. This safety threshold may change according to the application set-up and environments of the processing.

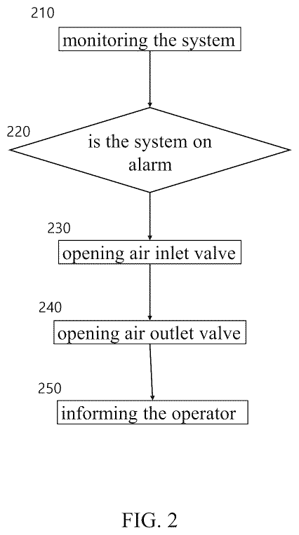

FIG. 2 illustrates a flowchart of the method for an extended safety system according to an embodiment.

The controller 132, in a step 210 of the method, may monitor the operation status of the substrate processing apparatus (or the whole system whichever suits the purpose best). In this step 210 of the method, the controller 132 may also control the air inlet valve 133 and the air outlet valve 134 to tightly close.

The controller 132, in a step 220 of the method, may determine the result of the monitoring of the system 100.

If the system 100 is normal condition, the controller 132 may keep monitoring the operation status of the system 100. On the contrary if the controller 132 determines that an alarm triggered, the controller 132 may control the air inlet valve 133 and the air outlet valve 134 to open.

The controller 132, in the steps of 230 and 240, may open the air inlet/outlet values.

Both the air inlet valve 133 and air outlet valve 134 may open simultaneously. Or the opening sequence of the two valves is interchangeable. That means that the air inlet valve 133 may open first then the air outlet valve 134 may open later or vice versa. The sequence may not matter as long as the time difference between the two openings is equal to or less than 10 ms. The time difference threshold value, i.e., 10 ms, may vary in different systems to accommodate system requirements and safety options. Generally speaking, the shorter the threshold value, the better the safety of the system.

The controller 132, in a step 250 of the method, may notify an operator or user of the alarm status of the system 100. This step 250 may also be executed just after the step 220 when the controller 132 determines that the operation status of the system 100 may be an alarm status.

The above-described arrangements of system and method are merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. An enhanced safety system using a process cooling water (PCW) in substrate processing, the system comprises:
a substrate processing apparatus configured to process the substrates, the apparatus comprising a chamber and a showerhead;
an input line configured to receive a process cooling water (PCW) from an outside PCW source for cooling the chamber and the showerhead in the substrate processing apparatus;
an inlet valve disposed at an entrance of the input line to control an input of the PCW into the input line;
a drain line configured to gather the PCW from the substrate processing apparatus used for cooling the chamber and the showerhead, the drain line also being configured to exhaust the gathered PCW;
a plurality of channels connecting the input line and the drain line, wherein the PCW flows inside of the channels, and wherein each of the plurality of channels is proximate to the chamber and the showerhead respectively; and
a safety unit configured to inject a compressed dry air (CDA) into the input line and/or configured to purge the CDA and the PCW from the plurality of channels and the drain line.

2. The system according to the claim 1, the safety unit further comprises:
an air tank containing the CDA;
an air inlet valve controlling an injection of the CDA into the input line;
an air outlet valve controlling an exhaust of the CDA from the drain line; and
a controller configured to control the open/close of the air inlet valve and the air outlet valve.

3. The system according to the claim 2, wherein the controller further configured to monitor a status of the system.

4. The system according to the claim 3, wherein the controller further configured to open the air inlet valve and the air outlet valve when a system alarm is triggered.

5. The system according to the claim 4, wherein the time difference between openings of the air inlet valve and air outlet valve is equal to or less than 10 ms.

6. A safety securing method used in a substrate processing system, wherein the system comprises an input line for injecting process cooling water (PCW) for cooling the system and a drain line for exhausting the PCW from the system, the method comprises:
monitoring a status of the system;
determining whether the system status is on alarm;
opening an air inlet valve to inject a compressed dry air (CDA) into the input line if the monitored status is on alarm; and
opening an air outlet valve to purge the CDA and the PCW from the system if the monitored status is on alarm.

7. The method according to the claim 6, further comprising:
sending messages to an operator of the alarm and/or valve openings if the monitored status is on alarm.

8. A safety system for a substrate processing apparatus using a process cooling water (PCW), the apparatus comprising a chamber and a showerhead, an input line configured to receive a process cooling water (PCW), a drain line configured to gather the PCW and exhaust the gathered PCW and a plurality of channels connecting the input line and the drain line, wherein the PCW flows inside of the channels, the system comprises:
an air tank containing a compressed dry air (CDA);
an air inlet path connecting the air tank to the input line;
an air inlet valve disposed on the air inlet path and controlling an injection of the CDA into the input line;
an air outlet path connecting the drain line to an outside leak tray;
an air outlet valve disposed on the air outlet path and controlling an exhaust of the CDA from the drain line; and
a controller configured to control the open/close of the air inlet valve and the air outlet valve.
